(19) United States
(12) Patent Application Publication
(10) Pub. No.: US 2022/0199568 A1
(43) Pub. Date: Jun. 23, 2022

(54) MODULE

(71) Applicant: Murata Manufacturing Co., Ltd., Nagaokakyo-shi (JP)

(72) Inventors: Yoshihito OTSUBO, Nagaokakyo-shi (JP); Motohiko KUSUNOKI, Nagaokakyo-shi (JP)

(21) Appl. No.: 17/654,424

(22) Filed: Mar. 11, 2022

Related U.S. Application Data
(63) Continuation of application No. PCT/JP2020/035345, filed on Sep. 17, 2020.

(30) Foreign Application Priority Data
Sep. 27, 2019 (JP) 2019-176921

(51) Int. Cl. H01L 23/00; H01L 23/31; H01L 23/498; H01L 23/552

(52) U.S. Cl. CPC H01L 24/48; H01L 23/3121; H01L 23/49822; H01L 23/49838; H01L 2924/3025; H01L 2224/48091; H01L 2224/48111; H01L 2924/19107; H01L 23/552

(57) ABSTRACT

A module includes: a board having a first surface; a first component and a second component mounted on the first surface; and a wire disposed to extend across both the first component and the second component. The wire has one end and the other end that are both connected to the first surface, and the wire is grounded. As seen in a direction perpendicular to the first surface, the first component is located closer to the one end than the second component, a portion of the wire that is furthest from the first surface is located closer to the one end than to the other end, and the second component has an upper surface located lower than an upper surface of the first component.

### CROSS REFERENCE TO RELATED APPLICATION

This is a continuation of PCT/JP2020/035345 filed on Sep. 17, 2020, which claims priority from Japanese Patent Application No. 2019-176921 filed on Sep. 27, 2019. The contents of these application are incorporated herein by reference in their entireties.

### BACKGROUND OF THE DISCLOSURE

### Field of the Disclosure

The present disclosure relates to a module.

### Description of the Related Art

U.S. Pat. No. 9,761,537 B2 (PTL 1) describes a structure in which wire bonding is used to shield electromagnetic waves. FIGS. 7 and 9 of this literature also illustrate structures in which wire bonding is performed across mounted components.

Generally, wire bonding is performed in a two-step process of first bonding and second bonding. The following description assumes that a first target portion and a second target portion are electrically connected by a wire. Initially, in the first bonding, a tip of the wire held by a tool is melted into a ball, which is then joined to the first target portion. Then, in the second bonding, the wire whose one end has already been joined to the first target portion by the first bonding is routed, and a point in the middle of the wire is pressed against the second target portion and melted and thereby joined thereto. The rest of the wire is cut.

PTL 1: U.S. Pat. No. 9,761,537 B2

### BRIEF SUMMARY OF THE DISCLOSURE

Usually, inclination of the wire varies between the joined portion by the first bonding and the joined portion by the second bonding. The joined portion by the first bonding can be joined in such a way that the wire extends in a substantially perpendicular direction from the first target portion, whereas the angle formed between a surface of the second target portion and the wire is relatively small at the joined portion by the second bonding. Stated another way, the wire is inclined. When both the first target portion and the second target portion are on the surface of a board, extra space is needed in the vicinity of the second joined portion for joining the wire, in consideration of the inclination of the wire at the second joined portion.

Therefore, it is an object of the present disclosure to provide a module capable of effectively using the space along a surface of a board while realizing a compartment shield with a wire.

In order to achieve the object described above, a module according to the present disclosure includes: a board having a first surface; a first component and a second component mounted on the first surface; and a wire disposed to extend across both the first component and the second component. The wire has one end and the other end that are both connected to the first surface; the wire is grounded; as seen in a direction perpendicular to the first surface, the first component is located closer to the one end than the second component; a portion of the wire that is furthest from the first surface is located closer to the one end than to the other end; and the second component has an upper surface located lower than an upper surface of the first component.

According to the present disclosure, although the wire tends to be lower at the other end, second component 3b as a shorter component is located closer to the other end than the first component, and therefore, the space under wire 4 can be efficiently utilized, to achieve effective use of the space along the surface of the board while realizing a compartment shield with the wire.

### BRIEF DESCRIPTION OF THE SEVERAL VIEWS OF THE DRAWINGS

FIG. 1 is a perspective view of a module in a first embodiment according to the present disclosure.

FIG. 2 is a plan view of the module in the first embodiment according to the present disclosure.

FIG. 3 is a cross-sectional view taken along a line III-III in FIG. 2.

FIG. 4 is a plan view of the module in the first embodiment according to the present disclosure, with an upper surface portion of a shield film and a sealing resin removed.

FIG. 5 is an enlarged view in the vicinity of a first bond end of a wire included in the module in the first embodiment according to the present disclosure.

FIG. 6 is an enlarged view in the vicinity of a second bond end of the wire included in the module in the first embodiment according to the present disclosure.

FIG. 7 is a plan view of a module in a second embodiment according to the present disclosure, with an upper surface portion of a shield film and a sealing resin removed.

FIG. 8 is a plan view of a module in a third embodiment according to the present disclosure, with an upper surface portion of a shield film and a sealing resin removed.

FIG. 9 is a cross-sectional view of the module in the third embodiment according to the present disclosure.

FIG. 10 is a plan view of a module in a fourth embodiment according to the present disclosure, with an upper surface portion of a shield film and a sealing resin removed.

FIG. 11 is a cross-sectional view of the module in the fourth embodiment according to the present disclosure.

FIG. 12 is an illustrative diagram of a structure in the vicinity of a second component of a modification of the module in the fourth embodiment according to the present disclosure.

FIG. 13 is a cross-sectional view of a module in a fifth embodiment according to the present disclosure.

FIG. 14 is a partial side view in the vicinity of a second component of the module in the fifth embodiment according to the present disclosure.

FIG. 15 is a partial perspective view in the vicinity of the second component of the module in the fifth embodiment according to the present disclosure.

FIG. 16 is a cross-sectional view of a module in a sixth embodiment according to the present disclosure.

### DETAILED DESCRIPTION OF THE DISCLOSURE

A dimensional ratio shown in the drawings does not necessarily faithfully represent an actual dimensional ratio and a dimensional ratio may be exaggerated for the sake of convenience of description. A concept up or upper or down or lower mentioned in the description below does not mean absolute up or upper or down or lower but may mean relative up or upper or down or lower in terms of a shown position. In the cross-sectional views below, multiple components that are not originally positioned to appear in the same cross section may be shown together for the sake of convenience of description.

### First Embodiment

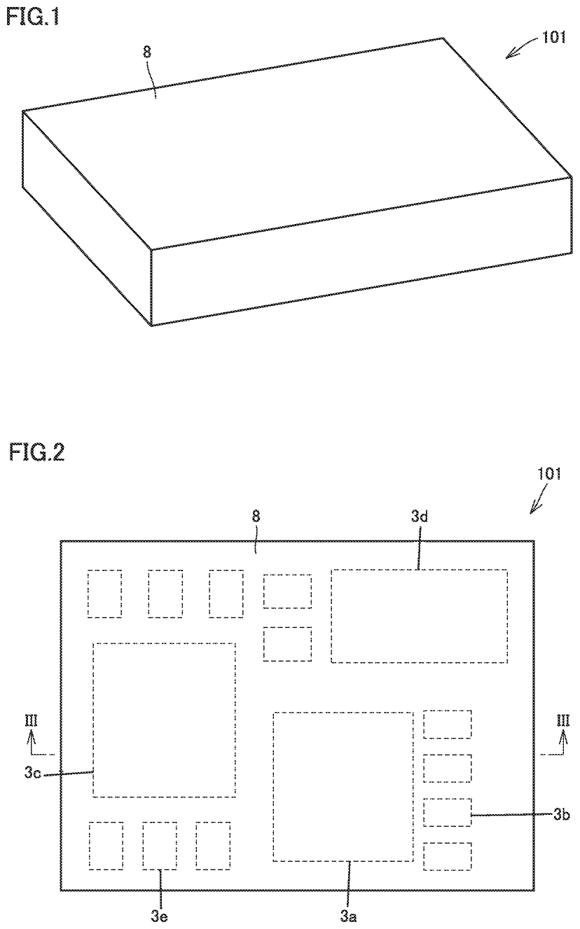

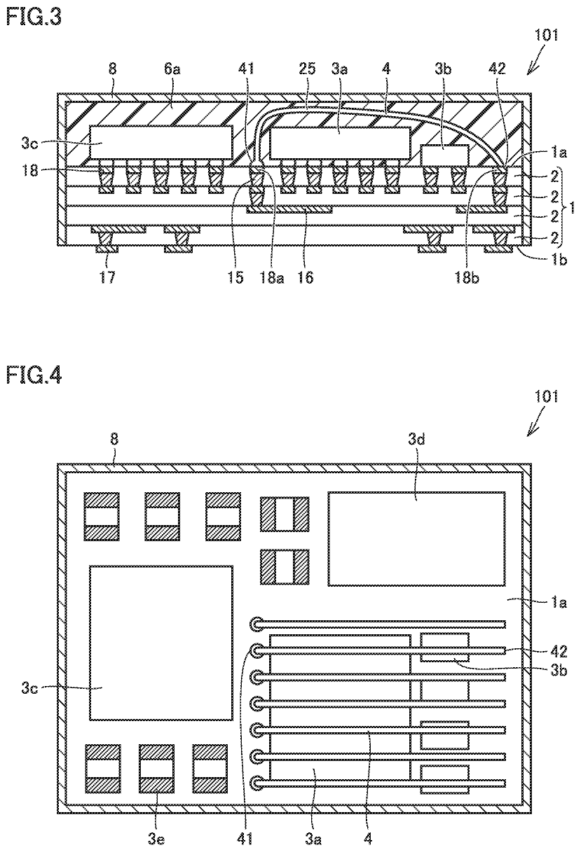

A module in a first embodiment according to the present disclosure will be described with reference to FIGS. 1 to 4. FIG. 1 shows a perspective view of a module 101 in the present embodiment. The upper surface and the side surface of module 101 are covered with a shield film 8. FIG. 2 shows a plan view of module 101. As shown in FIG. 2, module 101 has a first component 3a, a second component 3b, and components 3c, 3d, 3e embedded therein. FIG. 3 shows a cross-sectional view taken along a line III-III in FIG. 2.

Module 101 includes: a board 1 having a first surface 1a; first component 3a and second component 3b mounted on first surface 1a; and a wire 4 disposed to extend across both first component 3a and second component 3b. First component 3a is an IC element, for example. More specifically, first component 3a is a low noise amplifier (LNA), for example. First component 3a may be a power amplifier (PA), for example. Second component 3b is a chip component. Second component 3b may specifically be a chip capacitor or a chip resistor, for example. Second component 3b may be, together with first component 3a, a single shield target in the module, in other words, one of a transmission circuit, a reception circuit and the like, for example.

Board 1 is a wiring board. Board 1 is formed of a plurality of insulating layers 2 stacked on one another. Board 1 may be a ceramic multilayer board, or a resin multilayer board such as a printed wiring board. Board 1 has a second surface 1b located opposite to first surface 1a. Wire 4 has one end and the other end that are both connected to first surface 1a. The “one end” as used herein refers to a first bond end 41. The “other end” refers to a second bond end 42. In other words, the above-described one end is a start point side of wire bonding, and the above-described other end is an end point side of wire bonding. First bond end 41 is connected to a pad electrode 18a. Second bond end 42 is connected to a pad electrode 18b. Wire 4 is grounded.

A first sealing resin 6a is formed to cover all components mounted on first surface 1a. Shield film 8 is formed to cover the upper surface and the side surface of first sealing resin 6a, and the side surface of board 1. Shield film 8 is grounded. A conductor pattern 16 is disposed inside board 1. A conductor via 15 is electrically connected to conductor pattern 16. An external terminal 17 is provided on second surface 1b of board 1.

FIG. 4 shows a view from directly above, with an upper surface portion of shield film 8 and sealing resin 6a removed. As seen in a direction perpendicular to first surface 1a, first component 3a is located closer to the one end than second component 3b. As shown in FIG. 3, a portion 25 of wire 4 that is furthest from first surface 1a is located closer to the one end than to the other end. Second component 3b has an upper surface located lower than an upper surface of first component 3a.

In the present embodiment, since wire 4 is disposed to extend across both first component 3a and second component 3b, a compartment shield is created for first component 3a and second component 3b. In that case, due to the fact that portion 25 of wire 4 that is furthest from first surface 1a is located closer to the one end than to the other end, wire 4 tends to be lower in the vicinity of the other end. However, as seen in the direction perpendicular to first surface 1a, first component 3a as a taller component is located closer to the one end than second component 3b, and second component 3b as a shorter component is located closer to the other end than first component 3a. Thus, the space under wire 4 can be efficiently utilized to dispose first component 3a and second component 3b. In the present embodiment, therefore, the space along the surface of board 1 can be effectively used while a compartment shield with wire 4 is realized.

The portion where each of both ends of wire 4 is connected to first surface 1a is described in more detail. FIG. 5 shows an enlarged view of the portion where first bond end 41 as the one end is electrically connected to first surface 1a. First bond end 41 is connected to first surface 1a through pad electrode 18a. A ball-shaped portion is formed at first bond end 41. At first bond end 41, wire 4 extends so as to form an angle A with respect to first surface 1a.

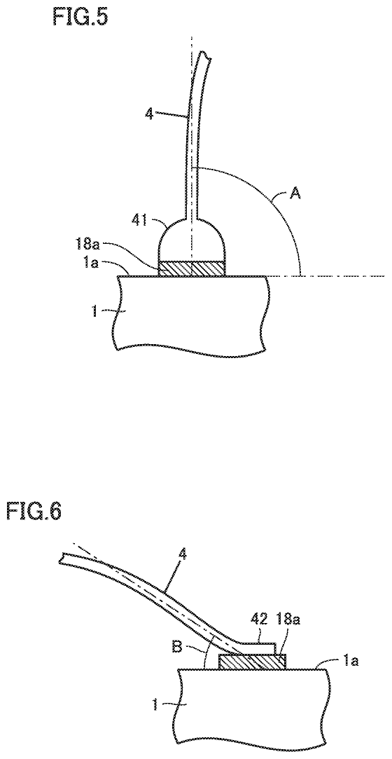

FIG. 6 shows an enlarged view of the portion where second bond end 42 as the other end is connected to first surface 1a. Second bond end 42 is connected to first surface 1a through pad electrode 18b. At second bond end 42, wire 4 extends so as to form an angle B with respect to first surface 1a. In this case, angle A is greater than angle B. In other words, the wire is inclined to a greater extent at the second bond side than at the first bond side.

As illustrated herein, it is preferable that the one end be connected so as to form first angle A with respect to first surface 1a, and that the other end be connected to first surface 1a so as to form second angle B smaller than first angle A.

As illustrated in the present embodiment, module 101 preferably includes the sealing resin that seals first component 3a and second component 3b, and shield film 8 formed to cover this sealing resin. In this case, first sealing resin 6a corresponds to the “sealing resin.”

### Second Embodiment

A module in a second embodiment according to the present disclosure will be described with reference to FIG. 7. A module 102 in the present embodiment is the same as module 101 described in the first embodiment in terms of its basic configuration, but includes the following configuration. FIG. 7 shows a view of module 102 in the present embodiment from directly above, with the upper surface portion of shield film 8 and sealing resin 6a removed. While a plurality of wires 4 are disposed in parallel with the sides of first component 3a in the first embodiment, a plurality of wires 4 are disposed obliquely with respect to the sides of first component 3a in the present embodiment. In other words, as seen in the direction perpendicular to first surface 1a, wires 4 are disposed obliquely with respect to the sides of first component 3a.

The same effect as that described in the first embodiment can be produced in the present embodiment as well. Further, in the present embodiment, since the plurality of wires 4 are disposed obliquely with respect to the sides of first component 3a, one of the ends of each wire 4 can be disposed along more sides of first component 3a. Therefore, the compartment shield can be made more robust.

### Third Embodiment

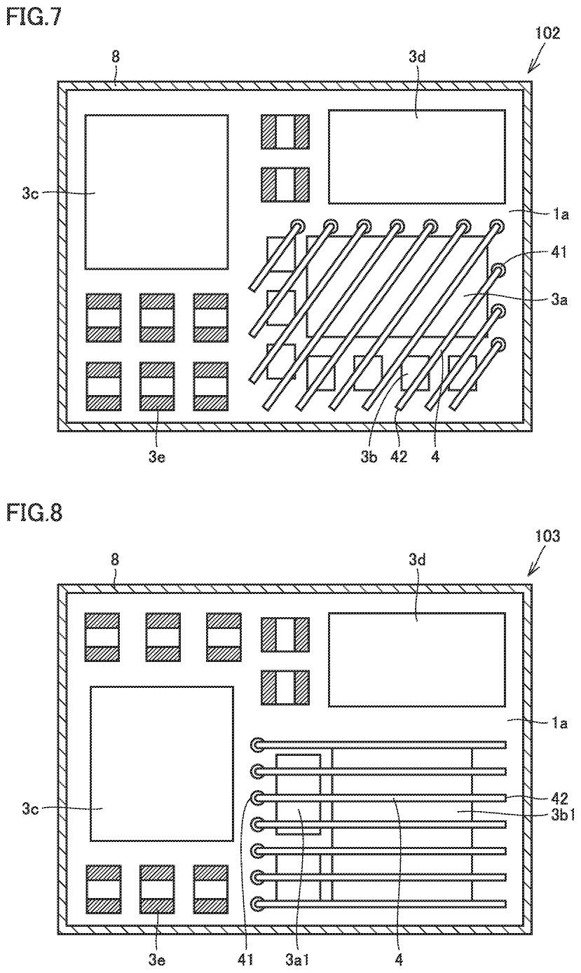

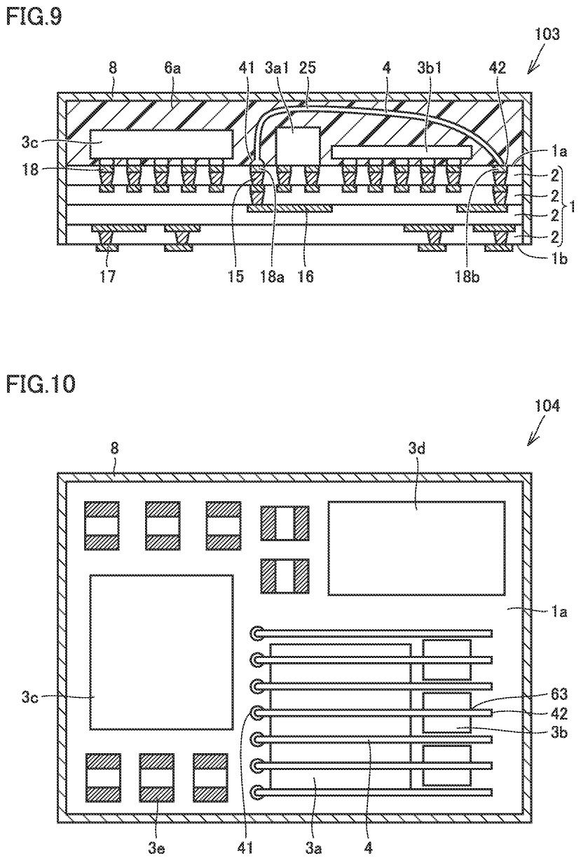

A module in a third embodiment according to the present disclosure will be described with reference to FIGS. 8 to 9. FIG. 8 shows a view of a module 103 in the present embodiment from directly above, with the upper surface portion of shield film 8 and sealing resin 6a removed. FIG. 9 shows a cross-sectional view of module 103. Module 103 in the present embodiment is the same as module 101 described in the first embodiment in terms of its basic configuration, but includes the following configuration.

In module 103, a first component 3a1 and a second component 3b1 are mounted on first surface 1a. Wire 4 is disposed to extend collectively across first component 3a1 and second component 3b1. First component 3a1 has a smaller area than second component 3b1 when viewed from above. First component 3a1 has an upper surface higher than an upper surface of second component 3b1. Second component 3b1 is an IC element, for example. More specifically, second component 3b1 is a low noise amplifier (LNA), for example. Second component 3b1 may be a power amplifier (PA), for example.

The same effect as that described in the first embodiment can be produced in the present embodiment as well.

### Fourth Embodiment

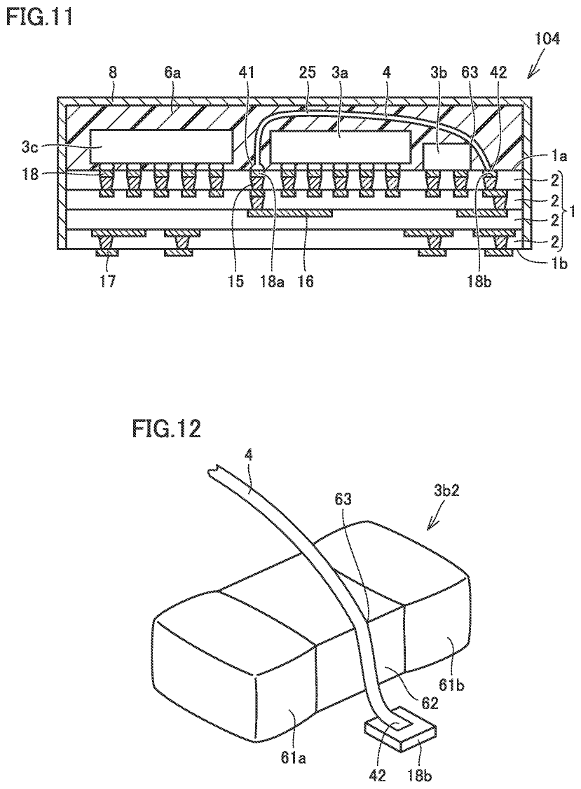

A module in a fourth embodiment according to the present disclosure will be described with reference to FIGS. 10 to 11. FIG. 10 shows a view of a module 104 in the present embodiment from directly above, with the upper surface portion of shield film 8 and sealing resin 6a removed. FIG. 11 shows a cross-sectional view of module 104. Module 104 in the present embodiment is the same as module 101 described in the first embodiment in terms of its basic configuration, but includes the following configuration.

In module 104, wire 4 is bent in contact with second component 3b. Wire 4 is bent in contact with a shoulder 63 of second component 3b. In the example illustrated herein, shoulder 63 is an insulating portion and there is no risk of a short circuit between wire 4 and second component 3b. Alternatively, even if the shoulder is an electrically conductive portion, if it is a ground electrode, there is no risk of a short circuit even when the wire and the shoulder are in contact with each other.

The same effect as that described in the first embodiment can be produced in the present embodiment as well. In the present embodiment, furthermore, since wire 4 is bent in contact with second component 3b, the other end of wire 4 can be connected at a steeper angle with respect to first surface 1a. In other words, angle B in FIG. 6 can be increased. In this manner, the limited space on first surface 1a can be effectively used.

(Modification)

While second component 3b which is a common rectangular parallelepiped is shown by way of example in FIG. 11, a second component 3b2 such as shown in FIG. 12 may be used in place of second component 3b. Second component 3b2 is a rectangular parallelepiped, and is a component having electrodes formed at its opposite ends in the longitudinal direction. Second component 3b2 includes electrodes 61a, 61b and a non-electrode portion 62. Non-electrode portion 62 is a middle portion sandwiched between electrodes 61a and 61b. When such second component 3b2 is mounted, wire 4 is in contact with shoulder 63 of non-electrode portion 62 of second component 3b2, as shown in FIG. 12. When wire 4 avoids the electrodes and is in contact with shoulder 63 of such non-electrode portion 62, wire 4 can be bent without generation of an undesired electrical connection. The configuration of second component 3b2 illustrated herein is merely illustrative.

### Fifth Embodiment

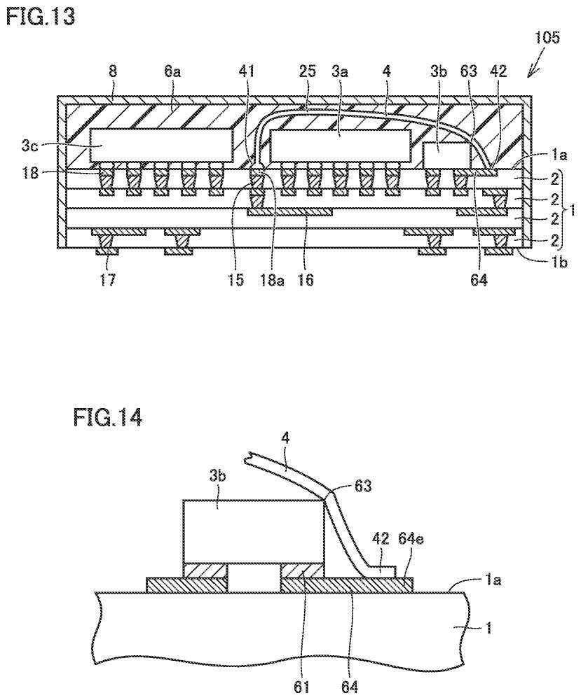

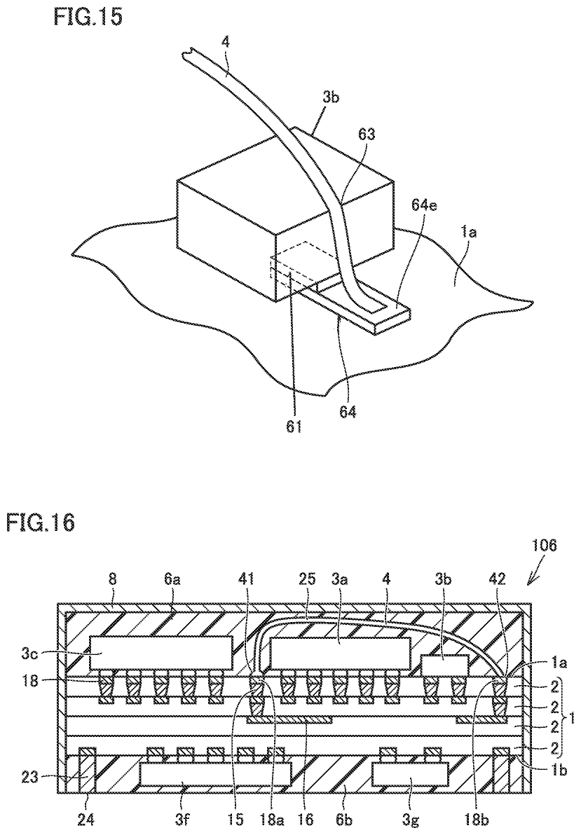

A module in a fifth embodiment according to the present disclosure will be described with reference to FIGS. 13 to 15. FIG. 13 shows a cross-sectional view of a module 105 in the present embodiment. Module 105 in the present embodiment is the same as module 104 described in the fourth embodiment in terms of its basic configuration, but includes the following configuration. FIGS. 14 and 15 each show an enlarged view in the vicinity of second component 3b. Second component 3b includes a first electrode 61 as an electrode for connection to board 1.

Second component 3b has first electrode 61, a second electrode 64 electrically connected to first electrode 61 is disposed on first surface 1a, second electrode 64 extends along first surface 1a so as to include a protruding portion 64e that protrudes outward from a projection area of second component 3b onto first surface 1a, and second bond end 42 as the other end is connected to protruding portion 64e. First electrode 61 and second electrode 64 may both be a GND electrode.

In the present embodiment, since second electrode 64 includes protruding portion 64e, and second bond end 42 as the other end is connected to protruding portion 64e, the electrical connection of second bond end 42 of wire 4 can be made more reliable.

### Sixth Embodiment

A module in a sixth embodiment according to the present disclosure will be described with reference to FIG. 16. FIG. 16 shows a cross-sectional view of a module 106 in the present embodiment. Module 106 in the present embodiment is the same as module 101 described in the first embodiment in terms of its basic configuration, but includes the following configuration.

Module 106 has a double-sided mounting structure. In other words, in module 106, board 1 has second surface 1b located opposite to first surface 1a, with at least one component mounted on second surface 1b. Specifically, in module 106, by way of example, components 3f and 3g are mounted on second surface 1b of board 1. Components 3f and 3g are sealed with a second sealing resin 6b. An external terminal 24 is provided on the lower surface of module 104. In the example shown herein, the lower surface of a columnar conductor 23 serves as external terminal 24. Columnar conductor 23 is disposed on second surface 1b. Columnar conductor 23 may be one of a pin, an electrode formed by plating, and a metal block. Columnar conductor 23 extends through second sealing resin 6b. A solder bump may be connected to the lower end of columnar conductor 23. The configuration of external terminal 24 shown herein is merely illustrative and not restrictive. A bump may be provided in place of columnar conductor 23.

The same effect as that described in the first embodiment can be produced in the present embodiment as well. In the present embodiment, more components can be mounted on board 1 because of the double-sided mounting structure.

Among the above-described embodiments, one or more of the embodiments may be employed in an appropriate combination.

The above embodiments disclosed herein are illustrative and non-restrictive in every respect. The scope of the present disclosure is defined by the terms of the claims, and is intended to include any modifications within the meaning and scope equivalent to the terms of the claims.
1 board; la first surface; lb second surface; 2 insulating layer; 3a, 3a1 first component; 3b, 3b1, 3b2 second component; 3c, 3d, 3e, 3f, 3g component; 4 wire; 6a first sealing resin; 6b second sealing resin; 8 shield film; 15 conductor via; 16 conductor pattern; 17, 24 external terminal; 18, 18a, 18b pad electrode; 23 columnar conductor; 25 (furthest) portion; 41 first bond end; 42 second bond end; 61 first electrode; 61a, 61b electrode (of second component); 62 non-electrode portion (of second component); 63 shoulder (of second component); 64 second electrode; 64e protruding portion; 101, 102, 103, 104, 105, 106 module.

1. A module comprising:
a board having a first surface;
a first component and a second component mounted on the first surface; and
a wire disposed to extend across both the first component and the second component, wherein
the wire has one end and the other end both connected to the first surface,
the wire is grounded,
as seen in a direction perpendicular to the first surface, the first component is located closer to the one end than the second component,
a portion of the wire furthest from the first surface is located closer to the one end than to the other end, and
the second component has an upper surface located lower than an upper surface of the first component.

2. The module according to claim 1, wherein
the one end is connected so as to form a first angle with respect to the first surface, and the other end is connected to the first surface so as to form a second angle smaller than the first angle.

3. The module according to claim 1, wherein
the one end is a start point side of wire bonding.

4. The module according to claim 1, wherein
the wire is bent in contact with the second component.

5. The module according to claim 4, wherein
the second component has a first electrode, wherein a second electrode electrically connected to the first electrode is disposed on the first surface, the second electrode extends along the first surface so as to include a protruding portion protruding outward from a projection area of the second component onto the first surface, and the other end is connected to the protruding portion.

6. The module according to claim 1, wherein
as seen in the direction perpendicular to the first surface, the wire is disposed obliquely with respect to a side of the first component.

7. The module according to claim 1, comprising:
a sealing resin sealing the first component and the second component; and
a shield film provided to cover the sealing resin.

8. The module according to claim 1, wherein
the board has a second surface located opposite to the first surface, and at least one component is mounted on the second surface.

9. The module according to claim 2, wherein
the one end is a start point side of wire bonding.

10. The module according to claim 2, wherein
the wire is bent in contact with the second component.

11. The module according to claim 3, wherein
the wire is bent in contact with the second component.

12. The module according to claim 2, wherein
as seen in the direction perpendicular to the first surface, the wire is disposed obliquely with respect to a side of the first component.

13. The module according to claim 3, wherein
as seen in the direction perpendicular to the first surface, the wire is disposed obliquely with respect to a side of the first component.

14. The module according to claim 4, wherein
as seen in the direction perpendicular to the first surface, the wire is disposed obliquely with respect to a side of the first component.

15. The module according to claim 5, wherein
as seen in the direction perpendicular to the first surface, the wire is disposed obliquely with respect to a side of the first component.

16. The module according to claim 2, comprising:
a sealing resin sealing the first component and the second component; and
a shield film provided to cover the sealing resin.

17. The module according to claim 3, comprising:
a sealing resin sealing the first component and the second component; and
a shield film provided to cover the sealing resin.

18. The module according to claim 4, comprising:
a sealing resin sealing the first component and the second component; and
a shield film provided to cover the sealing resin.

19. The module according to claim 5, comprising:
a sealing resin sealing the first component and the second component; and
a shield film provided to cover the sealing resin.

20. The module according to claim 6 comprising:
a sealing resin sealing the first component and the second component; and
a shield film provided to cover the sealing resin.
